(19) United States
(12) Patent Application Publication
(10) Pub. No.: US 2025/0275234 A1
(43) Pub. Date: Aug. 28, 2025

(54) SEMICONDUCTOR DEVICE INCLUDING FORKSHEET TRANSISTOR STRUCTURE AND EARLY-FORMED GATE CUT STRUCTURE

(71) Applicant: SAMSUNG ELECTRONICS CO., LTD., Suwon-si (KR)

(72) Inventors: Seung Min SONG, Halfmoon, NY (US); Kang-ill SEO, Springfield, VA (US)

(73) Assignee: SAMSUNG ELECTRONICS CO., LTD., Suwon-si (KR)

(21) Appl. No.: 18/753,384

(22) Filed: Jun. 25, 2024

Related U.S. Application Data
(60) Provisional application No. 63/557,863, filed on Feb. 26, 2024.

(51) Int. Cl. H01L 27/092; H01L 29/06; H01L 29/423; H01L 29/775; H01L 29/786

(52) U.S. Cl. CPC H10D 84/85; H10D 30/43; H10D 30/6735; H10D 30/6757; H10D 62/121

(57) ABSTRACT

Provided is a semiconductor device which includes: a 1^{st} transistor including a 1^{st} channel structure and a 1^{st} gate structure on the 1^{st} channel structure; a 2^{nd} transistor including a 2^{nd} channel structure and a 2^{nd} gate structure on the 2^{nd} channel structure; a 3^{rd} transistor including a 3^{rd} channel structure and a 3^{rd} gate structure on the 3^{rd} channel structure; an isolation wall between the 1^{st} channel structure and the 2^{nd} channel structure; a gate cut structure between the 1^{st} gate structure and the 2^{nd} gate structure; and a 1^{st} active isolation structure between the 1^{st} channel structure and the 3^{rd} channel structure, below a level of a bottom surface of the 1^{st} channel structure or the 3^{rd} channel structure, wherein the gate cut structure penetrates the 1^{st} active isolation structure through a bottom surface thereof.

### CROSS-REFERENCE TO RELATED APPLICATION

This application is based on and claims priority from U.S. Provisional Application No. 63/557,863 filed on Feb. 26, 2024 in the U.S. Patent and Trademark Office, the disclosure of which is incorporated herein in its entirety by reference.

### BACKGROUND

### 1. Field

Apparatuses and methods consistent with the disclosure relate to a semiconductor device including a forksheet transistor structure and a gate cut structure.

### 2. Description of Related Art

The nanosheet transistor was introduced to address shortcomings of the fin field-effect transistor (FinFET). The FinFET has one or more horizontally arranged vertical fin structures as a channel structure, in which three surfaces of each fin structure are surrounded by a gate structure, and the nanosheet transistor is characterized by one or more nanosheet layers vertically stacked on a substrate as a channel structure and a gate structure surrounding all four surfaces of each of the nanosheet layers. The nanosheet transistor is known to allow a better control of current and enable a higher device density than the FinFET in forming a semiconductor device. The nanosheet transistor is also referred to as gate-all-around (GAA) transistor, or as a multi-bridge channel field-effect transistor (MBCFET)

Recently, the nanosheet transistor has evolved into a forksheet transistor are which enables further miniaturization of a semiconductor device. The forksheet transistor structure may take a form of a combination of two nanosheet transistors with an isolation wall therebetween to separate channel structures, gate structures surrounding the nanosheet channel structures, and source/drain patterns formed on the channel structures, respectively, of the two nanosheet transistors. Thus, at each side of the isolation wall are formed a nanosheet channel structure which passes through a gate structure to connect source/drain patterns for each nanosheet transistor of the forksheet transistor structure.

Researches have been active in improving performance of a semiconductor device including forksheet transistors and a manufacture process of the same.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

According to an aspect of example embodiments, there is provided a semiconductor device which may include: a 1^{st} transistor including a 1^{st} channel structure and a 1^{st} gate structure on the 1^{st} channel structure; a 2^{nd} transistor including a 2^{nd} channel structure and a 2^{nd} gate structure on the 2^{nd} channel structure; a 3^{rd} transistor including a 3^{rd} channel structure and a 3^{rd} gate structure on the 3^{rd} channel structure; an isolation wall between the 1^{st} channel structure and the 2^{nd} channel structure; a gate cut structure between the 1^{st} gate structure and the 2^{nd} gate structure; and a 1^{st} active isolation structure between the 1^{st} channel structure and the 3^{rd} channel structure, below a level of a bottom surface of the 1^{st} channel structure or the 3^{rd} channel structure, wherein the gate cut structure penetrates the 1^{st} active isolation structure through a bottom surface of the 1^{st} active isolation structure.

According to an aspect of example embodiments, there is provided a semiconductor device which may include: a 1^{st} transistor structure including a 1^{st} channel structure; a 2^{nd} transistor structure including a 2^{nd} channel structure, and disposed at a 1^{st} side of the 1^{st} transistor structure; a 1^{st} active isolation structure between the 1^{st} channel structure and the 2^{nd} channel structure, below a bottom surface of the 1^{st} channel structure or the 2^{nd} channel structure; and a 2^{nd} active isolation structure at a 2^{nd} side of the 1^{st} transistor structure, opposite to the 1^{st} side, below the bottom surface of the 1^{st} channel structure or the 2^{nd} channel structure, wherein a bottom surface of the 1^{st} active isolation structure is at a level above a bottom surface of the 2^{nd} active isolation structure.

According to an aspect of example embodiments, there is provided a semiconductor device which may include: a 1^{st} transistor structure including a 1^{st} channel structure and a 1^{st} gate structure on the 1^{st} channel structure; a 2^{nd} transistor structure including a 2^{nd} channel structure and a 2^{nd} gate structure on the 2^{nd} channel structure, and disposed at a side of the 1^{st} transistor structure; a 1^{st} isolation structure between the 1^{st} fin structure and the 2^{nd} gate structure; and a 1^{st} active isolation structure between the 1^{st} channel structure and the 2^{nd} channel structure, below a bottom surface of the 1^{st} channel structure or the 2^{nd} channel structure, wherein the 1^{st} isolation structure penetrates the 1^{st} active isolation structure through a bottom surface of the 1^{st} active isolation structure.

According to an aspect of example embodiments, there is provided a method of manufacturing a semiconductor device, which may include: forming an initial channel structure; patterning the initial channel structure to form 1^{st} to 3^{rd} recesses and 1^{st} to 3^{rd} channel structures such that the 1^{st} recess is formed between the 1^{st} channel structure and the 3^{rd} channel structure, the 2^{nd} recess is formed between the 1^{st} channel structure and the 2^{nd} channel structure, and the 3^{rd} recess is formed at a side of the 2^{nd} channel structure opposite the 1^{st} recess with respect to the 2^{nd} recess; forming a 1^{st} isolation structure and a 2^{nd} isolation structure in the 1^{st} recess and the 2^{nd} recess, respectively; patterning the 1^{st} recess such that 1^{st} isolation structure therein is spaced apart from the 1^{st} channel structure and the 3^{rd} channel structure while the 2^{nd} isolation structure in the 2^{nd} recess contacts the 1^{st} channel structure and the 2^{nd} channel structure; forming 1^{st} to 3^{rd} source/drain patterns on the 1^{st} to 3^{rd} channel structures, respectively; and forming 1^{st} to 3^{rd} gate structures on the 1^{st} to 3^{rd} channel structures, respectively, such that the 1^{st} isolation structure is between the 1^{st} fin structure and the 3^{rd} gate structure, and the 2^{nd} isolation structure is between the 1^{st} gate structure and the 2^{nd} gate structure.

According to an aspect of example embodiments, there is provided a method of manufacturing a semiconductor device, which may include: forming an initial channel structure; dividing the initial channel structure into 1^{st} channel structure and the 2^{nd} channel structure; forming a 1^{st} isolation structure between the 1^{st} channel structure and the 2^{nd} channel structure, wherein that the 1^{st} isolation structure is spaced apart from the 1^{st} channel structure and the 2^{nd} channel structure; and forming a 1^{st} gate structure and a 2^{nd} gate structure on the 1^{st} channel structure and the 2^{nd} channel structure, respectively, after the forming the 1^{st} isolation structure such that the 1^{st} gate structure and the 2^{nd} gate structure are separated by the 1^{st} isolation structure and contact the 1^{st} isolation structure.

### BRIEF DESCRIPTION OF DRAWINGS

Example embodiments of the disclosure will be more clearly understood from the following detailed description taken in conjunction with the accompanying drawings.

FIGS. 1A and 1B illustrate a semiconductor device including a forksheet transistor structure and a gate cut structure, according to one or more embodiments.

FIG. 2 illustrate a semiconductor device including a forksheet transistor structure and a gate cut structure, according to one or more other embodiments.

FIGS. 3A through 3L illustrate cross-section views of intermediate semiconductor devices after respective steps of manufacturing a semiconductor device including a forksheet transistor structure and a gate cut structure, according to one or more other embodiments.

FIGS. 4A and 4B illustrate a flowchart of a method of manufacturing a semiconductor device including a forksheet transistor structures and a gate cut structure, according to one or more other embodiments.

FIG. 5 is a schematic block diagram illustrating an electronic device including a semiconductor device including a forksheet transistor structure and a gate cut structure, according to one or more embodiments.

### DETAILED DESCRIPTION

The embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, active (channel) layers, sacrificial layers, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions herebelow, the “left” element and the “right” element may also be referred to as a “1^{st}” element or a “2^{nd}” element, respectively, as long as their structural relationship is clearly understood in the context of the descriptions. Similarly, the terms a “lower” element and an “upper” element may be respectively referred to as a “1^{st}” element and a “2^{nd}” element with necessary descriptions to distinguish the two elements.

It will be understood that, although the terms “1^{st},” “2^{nd},” “3^{rd}” “4^{th}” “5^{th}” “6^{th}” etc. may be used herein to describe various elements, these elements should not be limited by these terms. These terms are only used to distinguish one element from another element. Thus, a 1^{st} element or a 1^{st} direction discussed in the description of an embodiment could be termed a 2^{nd} element or a 2^{nd} direction in a claim without departing from the teachings of the disclosure. Further, a 1^{st} element or a 1^{st} direction discussed in a claim could be termed a 2^{nd} element or a 2^{nd} direction in another claim having no dependency therebetween without departing from the teachings of the disclosure.

As used herein, expressions such as “at least one of,” when preceding a list of elements, modify the entire list of elements and do not modify the individual elements of the list. For example, the expression, “at least one of a, b and c” and “at least one of a, b or c” should be understood as including only a, only b, only c, both a and b, both a and c, both b and c, or all of a, b and c. Herein, when a term “same” is used to compare a dimension of two or more elements, the term may cover a “substantially same” dimension.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of semiconductor devices including a nanosheet transistor or a forksheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments.

Herebelow, various embodiments provide herebelow a structure of a semiconductor device including a forksheet transistor structure and a gate cut structure and a method of manufacturing the semiconductor device.

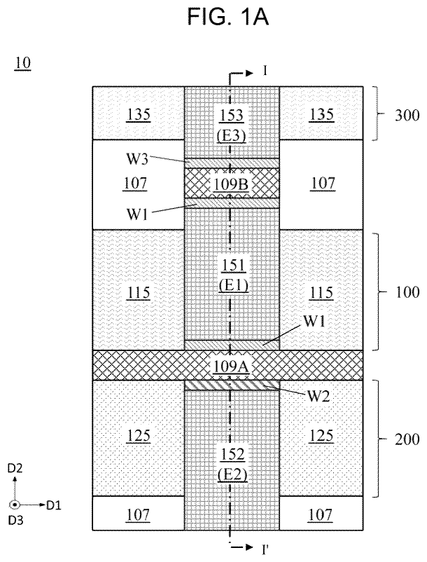

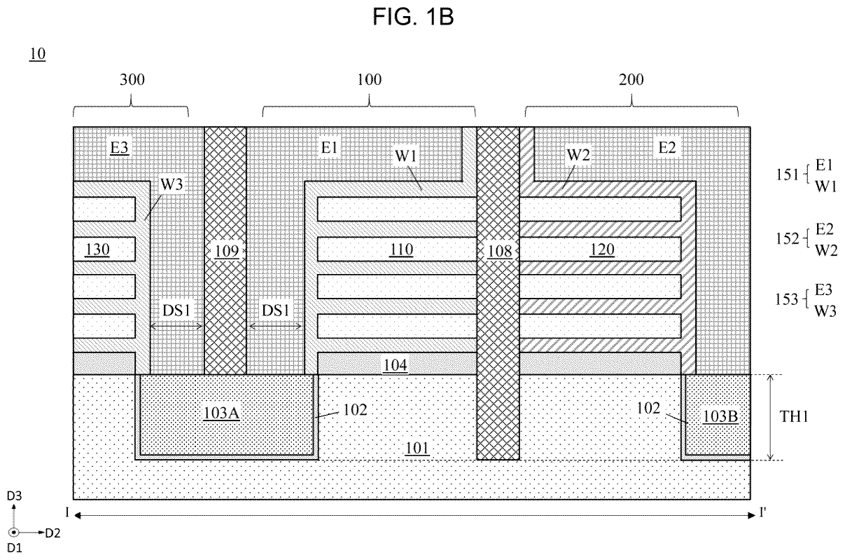

FIGS. 1A and 1B illustrate a semiconductor device including a forksheet transistor structure and a gate cut structure, according to one or more embodiments.

FIG. 1A is a plan view of a semiconductor device 10, and FIG. 1B is a cross-section view of the semiconductor device 10 shown in FIG. 1A taken along lines I-I′ thereof. As shown in FIGS. 1A and 1B, a D1 direction is a channel-length direction in which a current flows between two source/drain patterns (or source/drain regions) connected to each other through a channel structure, a D2 direction is a channel-width direction that intersects the D1 direction, and a D3 direction is a vertical direction that intersects the D1 and D2 directions both of which are horizontal directions.

Referring to FIGS. 1A and 1B, the semiconductor device 10 may include a 1^{st} transistor 100 and a 2^{nd} transistor 200 forming a forksheet transistor structure on a substrate 101. The semiconductor device 10 may also include a 3^{rd} transistor 300 at a side of the 1^{st} transistor 100 opposite to the 2^{nd} transistor 200 in the D2 direction. The 3^{rd} transistor 300 is only partly shown in FIGS. 1A and 1B. Each of the three transistors 100-300 may be a nanosheet transistor formed of a plurality of channel layers arranged one after above in the D3 direction as a channel structure of the transistor as will be described later. However, the 3^{rd} transistor 300 may be an independent nanosheet transistor or a part of another forksheet transistor structure. Although the semiconductor device 10 is shown to include three transistors 100-300 in FIGS. 1A and 1B, one or more additional transistors may be arranged in the D1, D2 and D3 directions to form the semiconductor device 10.

Between the 1^{st} transistor 100 and the 2^{nd} transistor may be formed an isolation wall 108 to form these two transistors 100 and 200 as a forksheet transistor structure. The isolation wall 108 may be formed to extend in the D1 and D3 directions. In addition, a 1^{st} active isolation structure 103A and a 2^{nd} active isolation structure 103B may be formed at two opposite sides of the 1^{st} transistor 100 in the substrate 101. Each of the active isolation structures 103A and 103B may include a barrier liner 102 at an outer surface thereof in the substrate 101. Further, a gate cut structure 109 may be formed between the 1^{st} transistor 100 and the 3^{rd} transistor 300. The gate cut structure 109 may also be formed to extend in the D1 and D3 directions like the isolation wall 108. These isolation structures including the gate cut structure 109 will be described later in detail.

The 1^{st} transistor 100 may include 1^{st} channel layers 110 as a 1^{st} channel structure on the substrate 101, a 1^{st} gate structure 151 surrounding the 1^{st} channel layers 110, and 1^{st} source/drain patterns 115 formed on the 1^{st} channel layers 110. The 1^{st} source/drain patterns 115 may be arranged in the D1 direction and connected through the 1^{st} channel layer 110 therebetween. Similarly, the 2^{nd} transistor 200 may include 2^{nd} channel layers 120 as a 2^{nd} channel structure on the substrate 101, a 2^{nd} gate structure 152 surrounding the 2^{nd} channel layers 120, and 2^{nd} source/drain patterns 125 on the 2^{nd} channel layers 120. The 2^{nd} source/drain patterns 125 may also be arranged in the D1 direction and connected through the 2^{nd} channel layers 120 therebetween. The 3^{rd} transistor 300 may include 3^{rd} channel layers 130 as a 3^{rd} channel structure on the substrate 101, a 3^{rd} gate structure 153 surrounding the 3^{rd} channel layers 130, and 3^{rd} source/drain patterns 135 formed on the 3^{rd} channel layers 130. The 3^{rd} source/drain patterns 135 may also be arranged in the D1 direction and connected to the 3^{rd} channel layers 130 therebetween.

The substrate 101 on which the channel layers 110-130 are formed may be a silicon (Si) substrate, and may include other materials such as silicon germanium (SiGe), silicon carbide (SiC), not being limited thereto. The 1^{st} to 3^{rd} channel layers 110, 120 and 130 may have been epitaxially grown from the substrate 101, and may be formed of or include the same material (e.g., Si) forming the substrate 101.

The 1^{st} to 3^{rd} source/drain patterns 115, 125 and 135 may have been epitaxially grown from the respective 1^{st} to 3^{rd} channel layers 110, 120 and 130 in a process of manufacturing the semiconductor device 10. The 1^{st} to 3^{rd} source/drain patterns 115, 125 and 135 may be formed of or include silicon (Si) or silicon germanium (SiGe), and doped with p-type impurities or n-type impurities. For example, in a case where the 1^{st} transistor 100 and the 3^{rd} transistor 300 are each of a p-type, the 1^{st} source/drain patterns 115 and the 3^{rd} source/drain patterns 135 may be formed of silicon germanium (SiGe) doped with boron (B), gallium (Ga) and/or indium (In). As another example, in a case where the 2^{nd} transistor 200 is of an n-type, the 2^{nd} source/drain patterns 125 may be formed of silicon (Si) doped with phosphorus (p), arsenic (As) and/or antimony (Sb). However, the disclosure is not limited thereto, and the source/drain patterns 115, 125 and 135 may each be any one of the p-type and the n-type, according to one or more other embodiments.

Between the source/drain patterns 115, 125 and 135 above the substrate 101 may be formed an interlayer dielectric (ILD) structure 107 to isolate the source/drain patterns 115, 125 and 135 from each other as shown in FIG. 1A.

Each of the 1^{st} to 3^{rd} gate structures 151, 152 and 153 may include a work-function metal layer and a gate electrode. For example, the 1^{st} gate structure 151 of the 1^{st} transistor 100 may include a 1^{st} work-function metal layer W1 surrounding the 1^{st} channel layers 110 and a 1^{st} gate electrode E1 on the 1^{st} work-function metal layer W1. The 2^{nd} gate structure 152 of the 2^{nd} transistor 200 may include a 2^{nd} work-function metal layer W2 surrounding the 2^{nd} channel layers 120, and a 2^{nd} gate electrode E2 on the 2^{nd} work-function metal layer W2. The 3^{rd} gate structure 153 of the 3^{rd} transistor 300 may include a 3^{rd} work-function metal layer W3 surrounding the 3^{rd} channel layers 130, and a 3^{rd} gate electrode E3 on the 3^{rd} work-function metal layer W3. A gate dielectric layer may be formed between the work-function metal layers W1-W3 and the gate electrodes E1-E3, respectively.

The work-function metal layers W1-W3 may each be formed of a metal such as copper (Cu), aluminum (Al), titanium (Ti), tantalum (Ta), tungsten (W), cobalt (Co), TiN, WN, TiAl, TiAlN, TaN, TiC, TaC, TiAlC, TaCN, TaSiN, and/or a combination thereof, not being limited thereto. However, the work-function metal layers W1-W3 may be formed of different materials among the above-listed materials depending on a polarity type of transistor that each of the work-function metal layers W1-W3 forms or a gate threshold voltage for each of the gate structures 151-153. The gate electrodes E1-E3 may each be formed of Cu, W, Al, Ruthenium (Ru), molybdenum (Mo), Co, and/or a combination thereof, not being limited thereto.

A bottom diffusion isolation (BDI) layer 104 may be formed between the substrate 101 and a portion of each of the work-function metal layers W1-W3 below each of the lowermost channel layers 110, 120 and 130, respectively. The BDI layer 104 may be formed of a dielectric material such as silicon nitride (e.g., SiN, SICN, SIBCN, etc.), not being limited thereto, to prevent current leakage from the gate structures thereabove to the substrate 101.

The isolation wall 108 formed between the two transistors 100 and 200 may extend in the D1 and D3 directions to separate the two transistors 100 and 200. For example, the isolation wall 108 may separate the 1^{st} channel layers 110, the 1^{st} gate structure 151 and the 1^{st} source/drain patterns 115 from the 2^{nd} channel layers 120, the 2^{nd} gate structure 152 and the 2^{nd} source/drain patterns 125, respectively.

The isolation wall 108 may be disposed between the 1^{st} channel layers 110 and the 2^{nd} channel layers 120, and contact these channel layers. The isolation wall 108 may also be disposed between the 1^{st} source/drain patterns 115 and the 2^{nd} source/drain patterns 125, and contact these source/drain patterns 115 and 125. Further, the isolation wall 108 may be disposed between the 1^{st} gate structure 151 and the 2^{nd} gate structure 152, and contact the 1^{st} work-function metal layer W1 and the 2^{nd} work-function metal layer W2.

The isolation wall 108 may be formed of a dielectric material such as silicon nitride or its composite (SiN, Si₃N₄, SiCN, SiBCN, etc.,) not being limited thereto. The isolation wall 108 may be formed to have a thickness TH1 from a top surface of the substrate 101 into the substrate 101 in the D3 direction.

The 1^{st} active isolation structure 103A may be formed in an upper portion of the substrate 101 between the 1^{st} channel layers 110 of the 1^{st} transistor 100 and the 3^{rd} channel layers 130 of the 3^{rd} transistor 300, and extend in the D1 direction. The 1^{st} active isolation structure 103A may separate an upper portion of the substrate 101 below the 1^{st} channel layers 110 and an upper portion of the substrate 101 below the 3^{rd} channel layers 130. The 2^{nd} active isolation structure 103B may be formed at an upper portion of the substrate 101 at a right side of the 2^{nd} channel layers 120 of the 2^{nd} transistor 200, opposite to the 1^{st} active isolation structure 103A in the D2 direction. The 2^{nd} active isolation structure 103B may also extend in the D1 direction. The 2^{nd} active isolation structure 103B may separate an upper portion of the substrate 101 below the 2^{nd} channel layers 120 and an upper portion of the substrate 101 below other channel layers of another transistor.

The upper portions of the substrate 101 on which the channel layers 110, 120 and 130 are formed may be referred to as active regions from which the channel layers 110 and 130 have been epitaxially grown in a process of manufacturing the semiconductor device 10, respectively.

Each of the active isolation structures 103A and 103B may have a top surface which is horizontally aligned with or coplanar with the top surface of the substrate 101. Each of the active isolation structures 103A and 103B may also be formed to have the thickness TH1 from the top surface of the substrate 101 into the substrate 101 in the D3 direction as the isolation wall 108.

The active isolation structures 103A and 103B may be formed of a dielectric material such as silicon oxide (e.g., SiO₂) to prevent current leakage between the transistors 100 and 300 through the two upper portions of the substrate 101. The active isolation structures 103A and 103B may each be referred to as a shallow trench isolation (STI) structure. The barrier liner 102 of the active isolation structures 103A and 103B may include a dielectric material such as silicon nitride (e.g., SiN, SiCN, SiBCN, etc.,), not being limited thereto, to prevent oxide erosion of the active isolation structures 103A and 103B in the substrate 101.

It is to be appreciated herein that the terms “separation” and “isolation” may be interchangeably used herein, and may refer to physical separation and/or electrical isolation.

In the meantime, the gate cut structure 109 may be formed to extend in the D1 direction to separate the 1^{st} gate structure 151 of the 1^{st} transistor 100 and the 3^{rd} gate structure 153 of the 3^{rd} transistor 300.

The gate cut structure 109 may be disposed between the 1^{st} gate electrode E1 and the 3^{rd} gate electrode E3 on the 1^{st} active isolation structure 103A, and contact these two gate electrodes E1, E3 and the 1^{st} active isolation structure 103A. Unlike the isolation wall 108 contacting the channel layers 110 and 120 at both sides thereof, the gate cut structure 109 may be spaced apart from the channel layers 110 and 130 at bother sides thereof by a same distance DS1. A bottom surface of the gate cut structure 109 may contact or may be coplanar with a top surface of the 1^{st} active isolation structure 103A.

The gate cut structure 109 may also be formed of a dielectric material such as silicon nitride or its composite (SiN, Si₃N₄, SiCN, SiBCN, etc.,) not being limited thereto, which may be the same as or different from the dielectric material forming the isolation wall 108. The gate cut structure 109 may have a width in the D2 direction which may be different from or the same as the isolation wall 108.

This gate cut structure 109 may have been formed by patterning a gate structure surrounding both the 1^{st} channel layers 110 and the 3^{rd} channel layers 130 into the two gate structures 151 and 153, which may be referred to as a replacement metal gate (RMG) process performed after a dummy gate structure surrounding the channel layers 110 and 130 is removed in the process of manufacturing the semiconductor device 10.

However, forming the gate cut structure 109 after formation of the gate structure or the dummy gate structure (which is to be replaced by the gate structure) is a very challenging step in the process of manufacturing the semiconductor device 10. This is because a precise high-aspect ratio etching has to be performed on the gate structure or the dummy gate structure from a top side surface thereof down to the substrate 101 in the D3 direction to form a recess where a dielectric material is to be filled in between two channel structures, that is, between the 1^{st} channel layers 110 and the 2^{nd} channel layers 120, so that at least a same channel-to-gate cut spacing can be provided to each of the two transistors 100 and 200.

Thus, the following embodiments provide a semiconductor device in which a gate cut structure is formed at the same time as an isolation wall of a forksheet transistor structure so that the above-described difficulty in forming the gate cut structure after formation a gate structure may be avoided.

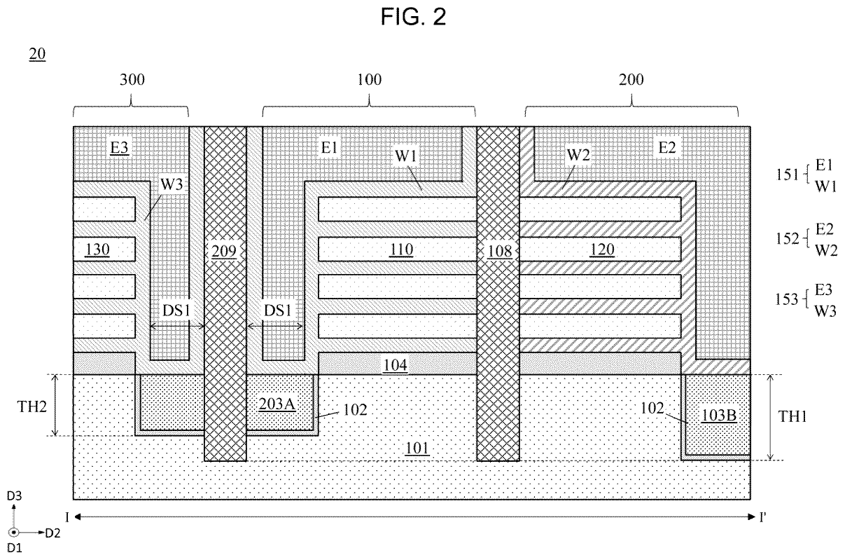

FIG. 2 illustrate a semiconductor device including a forksheet transistor structure and a gate cut structure, according to one or more other embodiments.

Referring to FIG. 2, a semiconductor device 20 may have the same structural elements as those of the semiconductor device 10 of FIGS. 1A and 1B, and thus, duplicate descriptions may be omitted herein. However, the semiconductor device 20 differs from the semiconductor device 10 by the structural shape of a 1^{st} active isolation structure 203A and a gate cut structure 209 formed thereon.

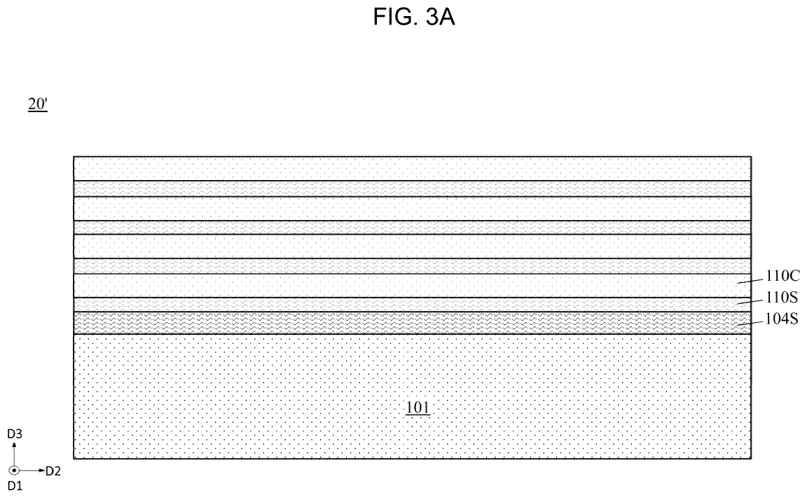

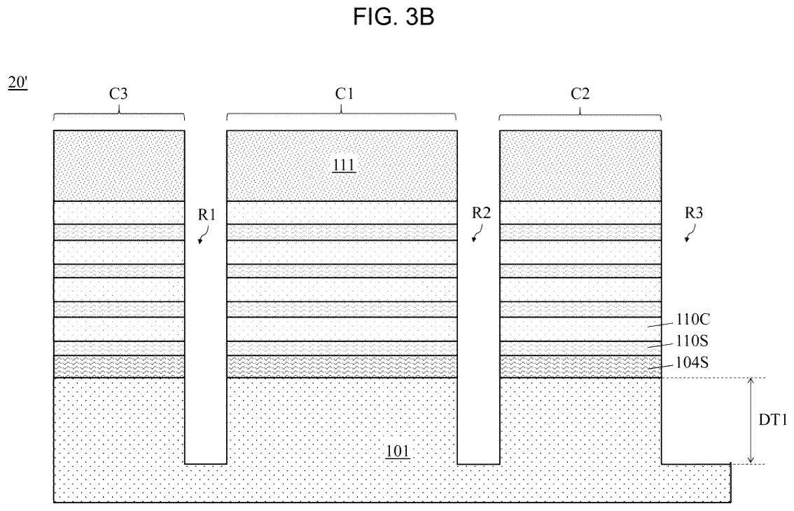

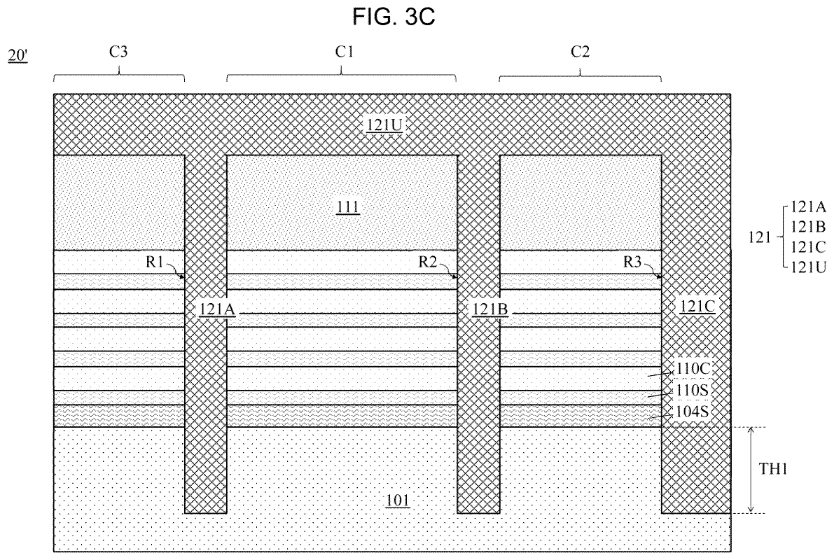

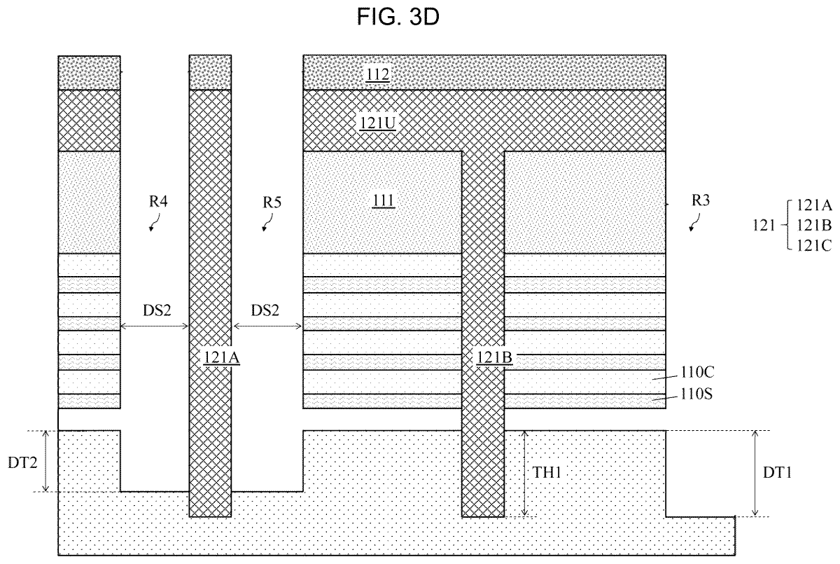

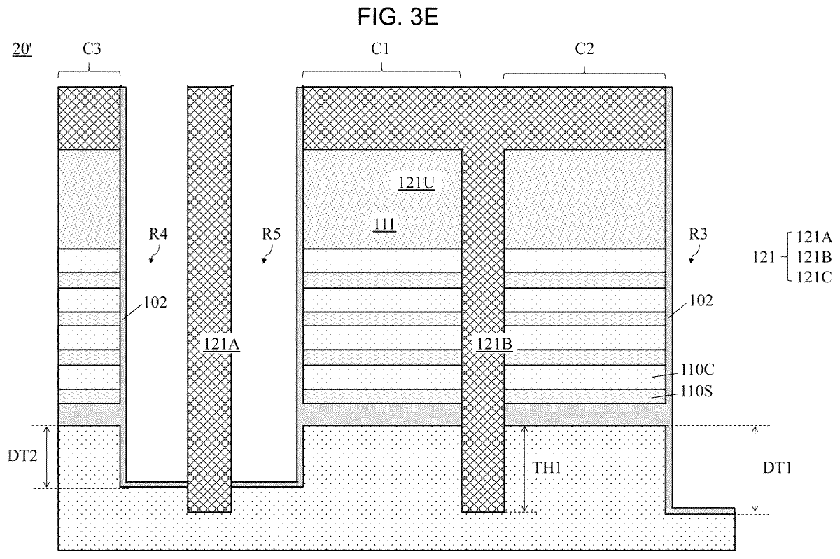

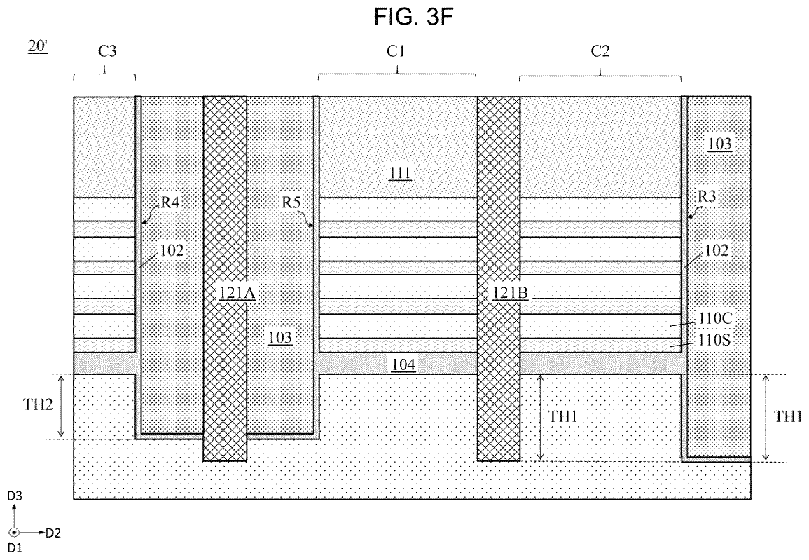

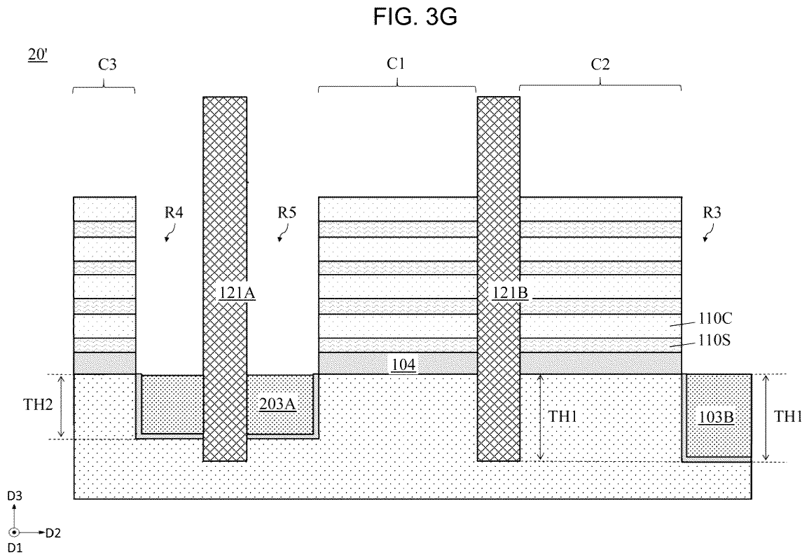

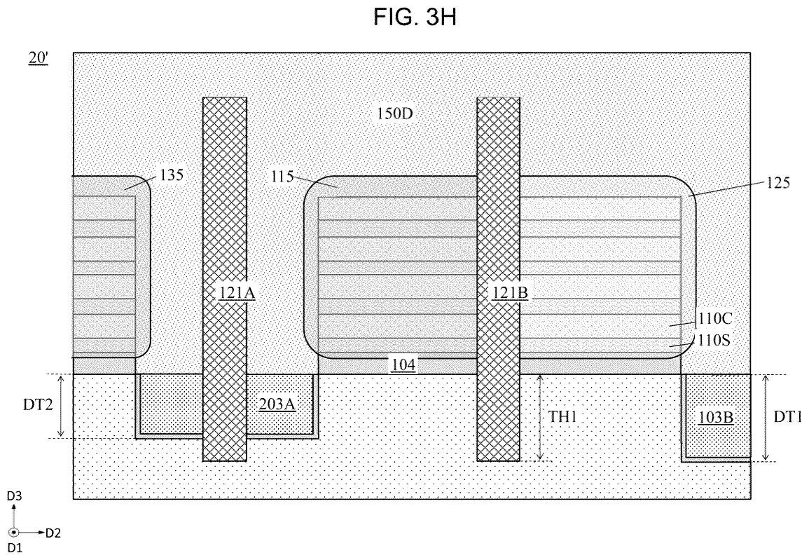

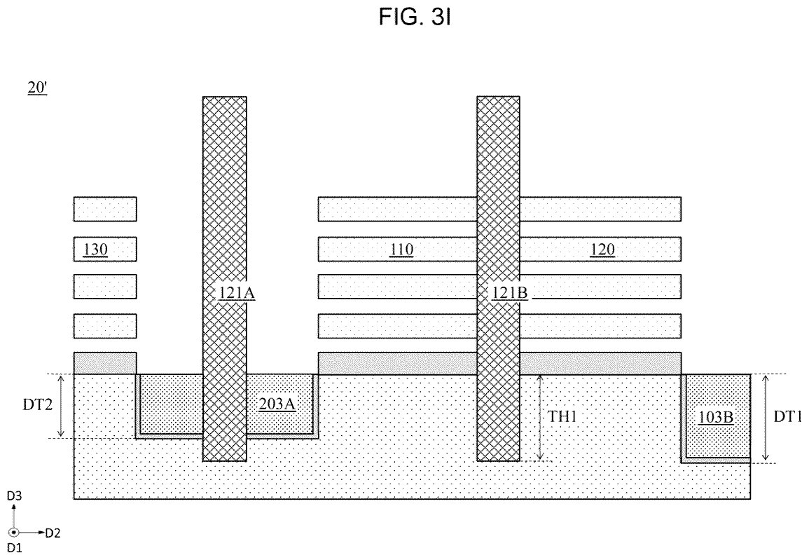

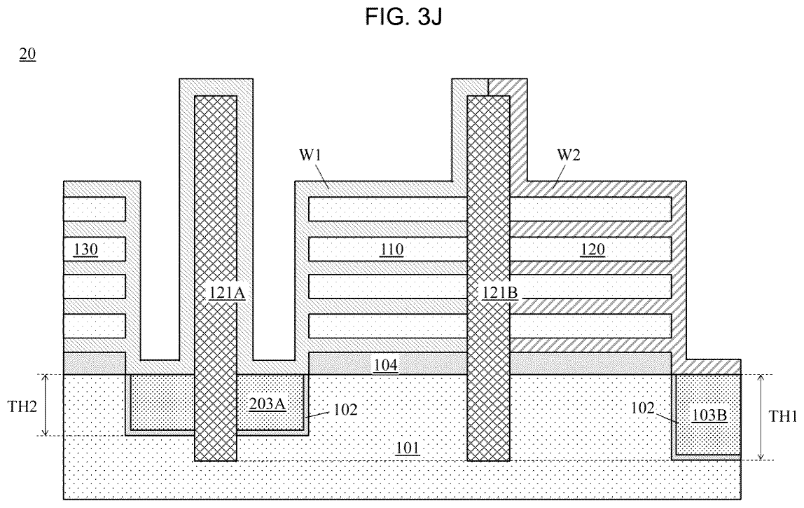

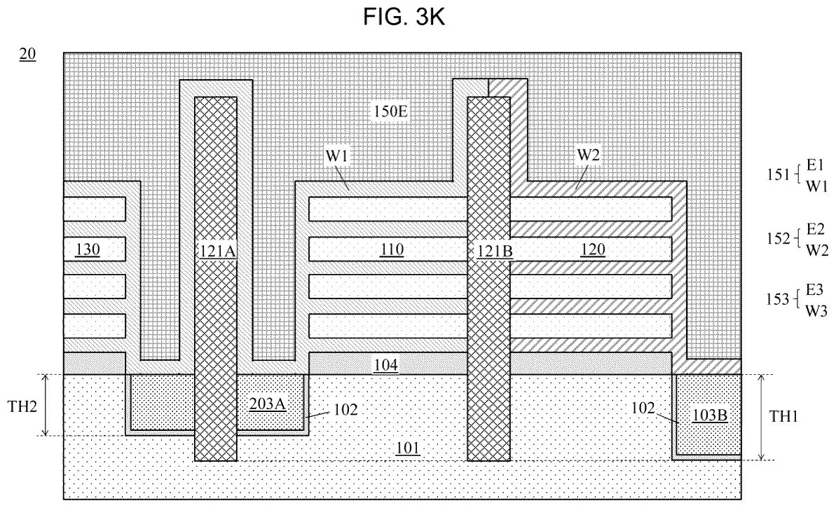

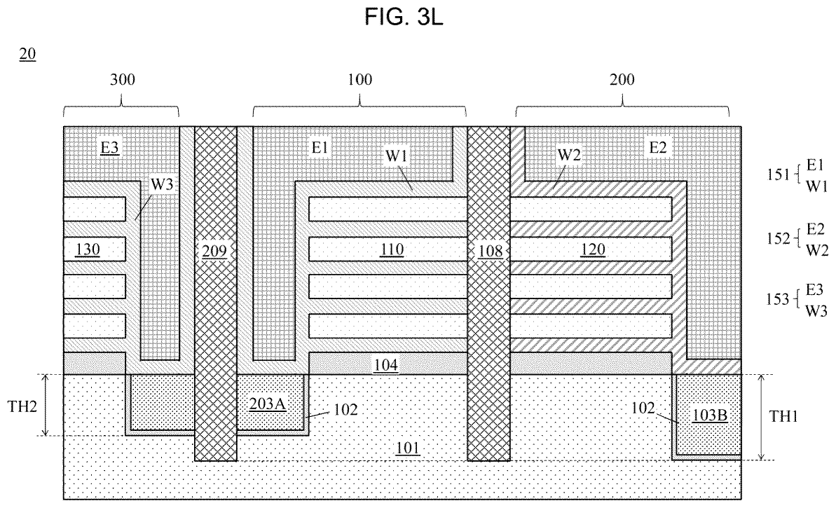

In the semiconductor device 20, the gate cut structure 209 may have been formed in an early step of manufacturing the semiconductor device 20. For example, the gate cut structure 209 may have been formed at the same time as the isolation wall 108 was formed to divide a single channel structure into two channel structures that would respectively form the 1^{st} channel layers 110 for the 1^{st} transistor 100 and the 2^{nd} channel layers 120 for the 2^{nd} transistor 200. A manufacturing process will be described later in reference to FIGS. 3A-3L.

In a case where the gate cut structure 209 and the isolation wall 108 are formed at the same time, the 1^{st} to 3^{rd} gate structures 151, 152 and 153 may be formed after the formation of the gate cut structure 209. Thus, the 1^{st} work-function metal layer W1 of the 1^{st} gate structure 151 and the 3^{rd} work-function metal layer W3 of the 3^{rd} gate structure 153 may be formed on two opposite side surfaces of the gate cut structure 209, respectively. Further, the gate cut structure 209 and the isolation wall 108 may have the same height in the D3 direction.

Moreover, early formation of the gate cut structure 209 may avoid the very challenging precise patterning of a gate cut structure to penetrate into a gate structure between two channel structures, thereby enabling manufacturing simplicity and improving a production yield for a semiconductor device.

In the meantime, the 1^{st} active isolation structure 203A may be formed to be shallower than the 2^{nd} active isolation structure 103B where no gate cut structure is formed. For example, while 2^{nd} the active isolation structure 103B has a thickness TH1 from a top surface of the substrate 101 into the substrate 101 in the D3 direction, the 1^{st} active isolation structure 203A may have a thickness TH2 which is smaller than the thickness TH1. In contrast, the isolation wall 108 and the gate cut structure 209 may each have the same thickness TH1 from a level of the top surfaces of the substrate 101 and the active isolation structures 203A and 103B, which is the same as the thickness TH1 of the 2^{nd} active isolation structure 103B.

The thickness difference between the 1^{st} active isolation structure 203A and the gate cut structure 209 below the top side surface of the 1^{st} active isolation structure 203A is provided because, in the process of manufacturing the semiconductor device 20, a recess to form the 1^{st} active isolation structure 203A may need to be formed shallower to provide structural strength and stability to the gate cut structure 209. Thus, the gate cut structure 209 may take a form of penetrating the 1^{st} active isolation structure 203A at a bottom surface thereof into the substrate 101 so that a bottom surface of the 1^{st} active isolation structure 203A may be at a level above a bottom surface of the gate cut structure 209.

Herebelow, a method of manufacturing the semiconductor device 20 is provided.

FIGS. 3A through 3L illustrate cross-section views of intermediate semiconductor devices after respective steps of manufacturing a semiconductor device including a forksheet transistor structure and a gate cut structure, according to one or more other embodiments.

The semiconductor device manufactured in reference to FIGS. 3A-3K may be the semiconductor device 20 shown in FIG. 2, and thus, the cross-section view of each of the intermediate semiconductor devices shown in FIGS. 3A-3K may correspond to that shown in FIG. 2. Thus, duplicate descriptions about the same structural elements described above in reference to FIG. 2 may be omitted, and the same reference characters or numerals may be used herebelow for brevity purposes.

Referring to FIG. 3A, a device structure 20′, which is an initial channel structure, including a plurality of nanosheet layers may be formed on a substrate 101.

The device structure 20′ may be formed by, for example, epitaxially growing a plurality of nanosheet layers from the substrate 101 in the D3 direction. The epitaxy performed in this step may include molecular beam epitaxy (MBE), vapor-phase epitaxy (VPE), etc. such that a bottom sacrificial layer 104′ is first grown, and then, a channel sacrificial layer 110S and a channel layer 110C are grown one after another in an alternating manner until a desired number of layers are obtained.

The channel layers 110C may each be formed of silicon (Si), and the bottom sacrificial layer 104′ and the channel sacrificial layers 110S may each be formed of silicon germanium (SiGe). However, germanium (Ge) concentration in the bottom sacrificial layer 104′ may be higher than in the channel sacrificial layers 110S. For example, the bottom sacrificial layer 104′ may have Ge concentration 50-60% while the channel sacrificial layers 110S may have Ge concentration 20-30%. Here, the bottom sacrificial layer 104′ and the channel sacrificial layers 110S are termed as such because these structural elements will be removed and replaced by other layers or structures in later steps.

Referring to FIG. 3B, the device structure 20′ obtained in the previous step may be patterned based on 1^{st} hard mask patterns 111 formed thereon to form 1^{st} to 3^{rd} recesses R1-R3 and corresponding 1^{st} to 3^{rd} channel structures C1, C2 and C3.

The 1^{st} hard mask patterns 111 may be formed by, for example, photolithography on a top side surface of the device structure 20′ at positions based on which the 1^{st} to 3^{rd} recesses R1-R3 can be patterned through the device structure 20′ into the substrate 101. Each of the recess R1-R3 may be formed to have a depth DT1 from a top surface of the substrate 101 into the substrate 101 in the D3 direction. The 1^{st} recess R1 may be provided for formation of a gate cut structure and an active isolation structure therein, and the 2^{nd} recess R2 may be provided for formation of an isolation wall of a forksheet transistor structure in a later step. The 3^{rd} recess R3 may be provided for formation of another active isolation structure in the substrate 101 in a later step.

Due to the recess patterning in this step, 1^{st} to 3^{rd} channel structures C1, C2 and C3 may be formed from the device structure 20′. The 1^{st} channel structure C1 may be formed between the 1^{st} recess R1 and the 2^{nd} recess R2, and the 2^{nd} channel structure C2 may be formed between the 2^{nd} recess R2 and the 3^{rd} recess R3. The 3^{rd} channel structure C3 may be formed at a left side of the 1^{st} recess R1. The 1^{st} channel structure C1 and the 2^{nd} channel structure C2 are to form two channel structures of a forksheet transistor structure, and the 3^{rd} channel structure is to form a channel structure of an adjacent transistor in later steps. Here, widths of the recesses R1-R3 in the D2 direction may not necessarily be the same, and different from one another.

The 1^{st} hard mask patterns 111 may be formed of silicon nitride, silicon oxide, or a composite thereof (e.g., SiN, Si₃N₄, SiBCN, SiCN, SiO₂, SiNOC, etc.), not being limited thereto.

Referring to FIG. 3C, an isolation material may be filled in the recesses R1-R3 to form an isolation structure 121.

The isolation structure 121 formed in this step may include a 1^{st} portion 121A filled in the 1^{st} recess R1, a 2^{nd} portion filled in the 2^{nd} recess R2, a 3^{rd} portion 121C in the 3^{rd} recess R3, and a 4^{th} portion above a level of a top surface of the 1^{st} hard mask patterns 111. The 1^{st} portion 121A contacting the 1^{st} channel structure C1 and the 3^{rd} channel structure C3 in the 1^{st} recess R1 is to form a gate cut structure after additional patterning, and the 2^{nd} portion 121B contacting the 1^{st} channel structure C1 and the 2^{nd} channel structure C2 is to form an isolation wall for a forksheet transistor structure in a later step.

As the isolation material is filled in each of the recesses R1-R3 having the depth DT1 in the substrate 101, the 1^{st} to 3^{rd} portions 121A-121C of the isolation structure 121 formed therein may have a thickness TH1 which is equal to the depth DT1. However, as the widths R1-R3 may be different from one another, the 1^{st} to 3^{rd} portions 121A-121C of the isolation structure 121 may also be different from one another.

The isolation material filling out the recesses R1-R3 may also be extended on the top surface of the device structure 20′ to form the 3^{rd} portion 121U of the isolation structure 121, and may be planarized at a top surface thereof by, for example, chemical-mechanical polishing (CMP) to form the isolation structure 121.

The formation of the isolation structure 121 may be performed by depositing a dielectric material such as silicon nitride or its composite (e.g., SiN, Si₃N₄, SiBCN, SiCN, etc.), not being limited thereto through, for example, physical vapor deposition (PVD), chemical vapor deposition (CVD), plasma-enhanced chemical vapor deposition (PECVD), or a combination thereof, not being limited thereto.

Referring to FIG. 3D, the channel structures C1-C3 with the isolation structure 121 thereon may be patterned based on 2^{nd} hard mask patterns 112 to form a 4^{th} recess R4 and a 5^{th} recess R5 and reopen the 3^{rd} recess R3. Further, the bottom sacrificial layer 104′ may be pulled out in this step.

The 2^{nd} hard mask patterns 112 may be formed by, for example, another photolithography on a top side surface of the isolation structure 121 at positions based on which the 3^{rd} recess R3 is reopened and the 4^{th} recess R4 and the 5^{th} recess R5 are newly patterned along two opposite side surfaces of the 1^{st} portion 121A of the isolation structure 121 through the 3^{rd} channel structure C3 and the 1^{st} channel structure C1 into the substrate 101.

Each of the 4^{th} recess R4 and the 5^{th} recess R5 may be formed to have a width DS2 so that the 1^{st} portion 121A of the isolation structure 121 is spaced apart from each of the 1^{st} channel structure C1 and the 3^{rd} channel structure C3 by the width DS2.

Further, each of the 4^{th} recess R4 and the 5^{th} recess R5 may be formed to have a depth DT2 which is smaller than the depth DT1 of the 3^{rd} recess R3 and the thickness TH1. For example, a bottom surface of the each of the 4^{th} recess R4 and the 5^{th} recess R5 may be above a level of a bottom surface of the 1^{st} portion 121A of the isolation structure 121. Otherwise, in a case where the depth DT2 is greater than or equal to the depth DT1, the 1^{st} portion 121A of the isolation structure 121 may not sustain on a bottom surface of the recesses R4 and R5 in subsequent steps of forming an active isolation structure therein. Thus, this smaller thickness DT2 of the recesses R4 and R5 may provide structural strength and stability to the 1^{st} portion 121A of the isolation structure 121, which is to become the gate cut structure in a later step.

In the meantime, as the 3^{rd} recess R3 is reopened, the 3^{rd} portion 121C of the isolation structure 121 and a part of the 4 ^{th} portion of the isolation structure 121 above the 3^{rd} portion 121C may be removed. Also in this step, the bottom sacrificial layer 104′ may be removed to provide a void for filling in a bottom isolation layer in a next step. The removal of the bottom sacrificial layer 104′ may be performed by selective patterning such as dry etching or wet etching using hydrofluoric acid (HF), which etches the bottom sacrificial layer 104′ formed of silicon germanium (SiGe) with a high germanium (Ge) concentration against the channel sacrificial layers 110S formed of silicon germanium (SiGe) with a low Ge concentration and the channel layers 110C formed of silicon (Si).

Referring to FIG. 3E, a bottom isolation layer 104 may be formed in the void provided by the removal of the bottoms sacrificial layer 104′ in the previous step, and a barrier liner 102 may be selectively formed on bottom surfaces of the 3^{rd} to 5^{th} recesses R3-R5 and side surfaces thereof exposing the channel structures C1-C3, and the 2^{nd} hard mask patterns may be removed. Further, the 2^{nd} hard mask patterns 112 may be removed thereafter.

The bottom isolation layer 104 may be formed to prevent current leakage from a work-function metal layer of a gate structures which is to replace the channel sacrificial layer 110S in a later step, and the barrier liner 102 may be formed to prevent erosion of an oxide material such as silicon oxide (SiO₂) which is to be formed thereon in the substrate 101 in a later step. The barrier liner 102 and the oxide material is to form an active isolation structure in a later step.

The formation of bottom isolation layer 104 and the barrier liner 102 may be performed by, for example, PVD, CVD, PECVD, atomic layer deposition (ALD), PEALD, or a combination thereof depositing a material such as silicon nitride or its composite (e.g., SiN, SiCN, SiBCN, etc.,) on the side surfaces and bottom surfaces of the recesses R3-R5, followed by selective etching of the deposited material from a top surface of the isolation structure 121 and side surfaces of the 1^{st} portion 121A of the isolation structure 121.

After the formation of the bottom isolation layer 104 and the barrier liner 102, the 2^{nd} hard mask patterns 112 used to form the 4^{th} recess R4 and the 5^{th} recess R5 and reopen the 3^{rd} recess R3 may be removed by, for example, ashing or stripping, not being limited thereto.

Referring to FIG. 3F, an initial active isolation structure 103 may be formed in the recesses R3-R5 with the barrier liner 102 thereon and planarized at top surfaces thereof by, for example, CMP such that a top surface of the initial active isolation structure 103 is horizontally aligned or coplanar with the top surface of the 1^{st} hard mask patterns 111. At this time, the 4^{th} portion 121U of the isolation structure 121 patterned in the previous step and a portions of the barrier liner 102 on side surfaces thereof may also be removed by the planarization of the initial active isolation structure 103.

The initial active isolation structure 103 in the 3^{rd} recess R3 may have a thickness TH1 below the top surface of the substrate 101 which is the same as the depth DT1 of the 3^{rd} recess R3, and the initial active isolation structure 103 in the 4^{th} recess R4 and the 5^{th} recess R5 may have a thickness TH2 below a level of the top surface of the substrate 101 which is the same as the depth DT2 of each of the 4^{th} recess R4 and the 5^{th} recess R5.

The initial active isolation structure 103 in the recesses R3-R5 is to form active isolation structures in a later step therein after necessary patterning operations.

Referring to FIG. 3G, the initial active isolation structure 103 filled in the recesses R3-R5 and the barrier liner 102 thereon are partially removed to form an active isolation structure including the remaining barrier liner 102 in the substrate 101.

The initial active isolation structure 103 and the barrier liner 102 thereon may be partially removed by, for example, dry etching or wet etching such that top surfaces thereof are at a level of a top surface of the substrate 101. By this partial removal of the initial active isolation structure 103 and the barrier liner 102 thereon, a 1^{st} active isolation structure 203A may be formed in the substrate 101 between upper portions of the substrate 101 below the 1^{st} channel structure C1 and the 3^{rd} channel structure C3, and a 2^{nd} active isolation structure 103B may be formed in the substrate 101 at a side of an upper portion of the substrate 101 below the 2^{nd} channel structure C2. Both of the active isolation structures 203A and 103B may be formed in the substrate 101 below a level of a bottom surface of at least one of the 1^{st} to 3^{rd} channel structures C1-C3. However, the 1^{st} active isolation structure 203A may have the thickness TH2 while the 2^{nd} active isolation structure 103B has the thickness TH1 which is greater than the thickness TH2.

Referring to FIG. 3H, a dummy gate structure 150D may be formed to surround the 1^{st} to 3^{rd} channel structures C1-C3, and 1^{st} to 3^{rd} source/drain patterns 115, 125 and 135 may be formed on the 1^{st} to 3^{rd} channel structures C1-C3, respectively.

The dummy gate structure 150D may be formed to reserve a space for a gate structure to be formed in a later step and provide a structural support for formation of source/drain patterns in a later step. The dummy gate structure 150D may be formed by, for example, PVD, CVD, PECVD or a combination thereof followed by planarization at a top surface thereof. The dummy gate structure 150D may include a material such as polycrystalline silicon (p-Si) or amorphous silicon (a-Si).

Subsequently, at least based on the dummy gate structure 150D, the 1^{st} to 3^{rd} source/drain patterns 115, 125 and 135 may be epitaxially grown from the channel layers 110C of the 1^{st} to 3^{rd} channel structures C1-C3. It is to be understood here that, in reality, the source/drain patterns 115, 125 and 135 may not be shown in a cross-section view of FIG. 3H because they are not positioned at this cross-section of the device structure 20′ corresponding to the line I-I shown in FIG. 1A. The source/drain patterns 115, 125 and 135 are shown only in FIG. 3H to assist description of a process of manufacturing the semiconductor device 20.

Referring to FIG. 31, the dummy gate structure 150D and the channel sacrificial layers 110S of the channel structures C1-C3 may be removed to release the channel layers 110C of the channel structures C1-C3.

The removal operation in this step may be performed by, for example, dry etching, wet etching, or a combination thereof, not being limited thereto, using an etchant, for example, as a mixture of nitric acid (HNO₃) and hydrofluoric acid (HF), not being limited thereto, to selectively remove the dummy gate structure 150D of polycrystalline silicon (p-Si) or amorphous silicon (a-Si) and the channel sacrificial layers 110S of silicon germanium (SiGe) against the channel layers 110C of silicon (Si).

With the removal of the dummy gate structure 150D and the channel sacrificial layers 110S, 1^{st} channel layers 110, 2^{nd} channel layers 120, and 3^{rd} channel layers 130 may remain in the 1^{st} to 3^{rd} channel structures for three transistors to be finished in a later step.

Referring to FIG. 3J, a 1^{st} work-function metal layer W1 may be formed to surround the 1^{st} channel layers 110 and the 3^{rd} channel layers, and the 2^{nd} work-function metal layer W2 may be formed 2^{nd} channel layers 120, respectively.

In a case where the 1^{st} work-function metal layer W1 surrounds both the 1^{st} channel layers 110 and the 3^{rd} channel layers as in this embodiment, two transistors respectively including the 1^{st} work-function metal layer W1 and the 3^{rd} work-function metal layer W3 may be of the same polarity type (e.g., p-type or n-type) or may have the same gate threshold voltage.

The 1^{st} work-function metal layer W1 surrounding the 1^{st} channel layers 110 and the 3^{rd} channel layers 130 may be extended to be formed on outer surfaces of the 1^{st} portion 121A of the isolation structure 121 exposed above a top surface of the 1^{st} active isolation structure 203A, the top surface of the 1^{st} active isolation structure 203A, and a left side surface and a left half of a top side surface of the 2^{nd} portion 121B of the isolation structure 121 exposed above the 1^{st} channel layers 110 and the 2^{nd} channel layers 120.

The 2^{nd} work-function metal layer W2 surrounding the 2^{nd} channel layers 120 may be extended to be formed on a top side surface of the 2^{nd} active isolation structure 103B and a right side surface and a right half of a top surface of the 2^{nd} portion 121B of the isolation structure 121 exposed above the 1^{st} channel layers 110 and the 2^{nd} channel layers 120.

In a case the 2^{nd} work-function metal layer W2 is formed of a material different from the 1^{st} work-function metal layer W1, a transistor including the 2^{nd} work-function metal layer W2 may be of a different polarity type or may have a different gate threshold voltage compared to a transistor including the 1^{st} work-function metal layer W1.

The formation of the work-function metal layers W1 and W2 may be performed by, for example, atomic layer deposition (ALD), not being limited thereto.

Referring to FIG. 3K, a gate electrode 150E may be formed to surround the work-function metal layers W1-W3 by, for example, PVD, CVD, PECVD, or a combination thereof, not being limited thereto.

Referring to FIG. 3L, the device structure 20′ obtained in the previous step may be patterned or planarized at a top surface thereof to divide the gate electrode 150E and the work-function metal layers W1 and W2 surrounded by the gate electrode 150E into 1^{st} to 3^{rd} gate structures 151-153, thereby forming 1^{st} to 3^{rd} transistors.

The patterning or planarization in this step may be performed by, for example, dry etching, wet etching and/or CMP, not being limited thereto.

By the patterning or planarization operation in this step, the gate electrode 150E may be divided into 1^{st} to 3^{rd} gate electrodes E1-E3, and the 1^{st} work-function metal layer W1 may be divided into two portions, one surrounded by the 1^{st} gate electrode E1 and the other surrounded by the 3^{rd} gate electrode E3. Herein, the work-function metal layer surrounded by the 1^{st} gate electrode may still be referred to as the 1^{st} work-function metal layer W1, and the work-function metal layer surrounded by the 3^{rd} gate electrode may be referred to as a 3^{rd} work-function metal layer W3.

Thus, the 2^{nd} portion 121B of the isolation structure 121 now becomes an isolation wall 108 which separates the 1^{st} channel layers 110, the 1^{st} work-function metal layer W1, the 1^{st} gate electrode E1, and the 1^{st} source/drain patterns 115 forming a 1^{st} transistor 100 from the 2^{nd} channel layers 120, the 2^{nd} work-function metal layer W2, the 2^{nd} gate electrode E2, and the 2^{nd} source/drain patterns 125 forming a 2^{nd} transistor 200, respectively. Accordingly, the 1^{st} transistor 100 and the 2^{nd} transistor 200 along with the isolation wall 108 may form a forksheet transistor structure.

Further, the 1^{st} portion 121A of the isolation structure 121 now becomes a gate cut structure 209 which separates the 1^{st} work-function metal layer W1 and the 1^{st} gate electrode E1 of the 1^{st} transistor 100 from the 3^{rd} work-function metal layer W3 and the 3^{rd} gate electrode E3 which forms a 3^{rd} transistor 300 along with the 3^{rd} channel layers 130 and the 3^{rd} source/drain patterns 135.

As described above, forming the isolation structure 121 both including the 1^{st} portion 121A for the gate cut structure 209 and the 2^{nd} portion 121B for the isolation wall 108 at an early step, may avoid the very challenging precise patterning of a gate cut structure to penetrate into a gate structure between two channel structures, thereby enabling manufacturing simplicity and improving a production yield for a semiconductor device.

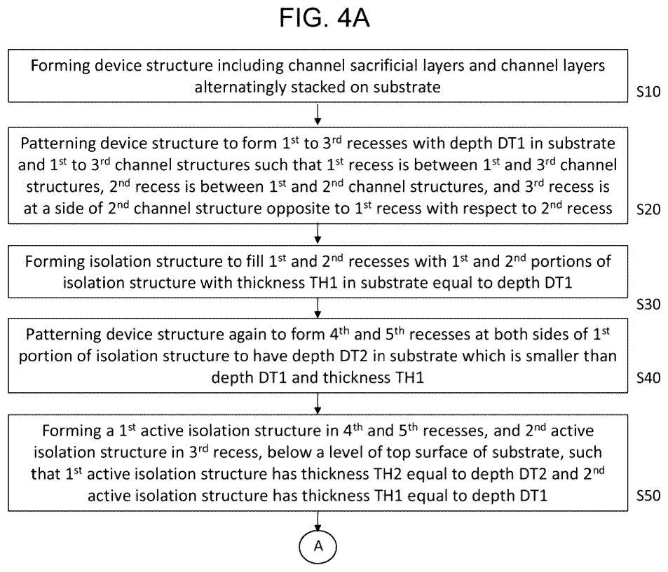

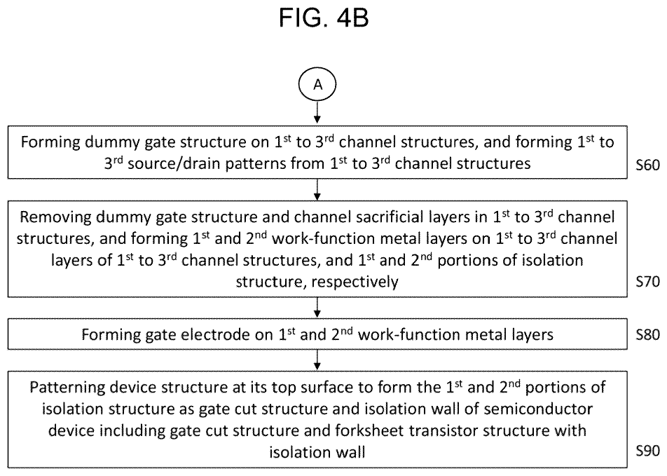

FIGS. 4A and 4B illustrate a flowchart of a method of manufacturing a semiconductor device including a forksheet transistor structures and a gate cut structure, according to one or more other embodiments. The method may be described herebelow in reference to FIGS. 3A-3L.

In step S10, a device structure (initial channel structure) 20′ may be formed on a substrate 101, in which a plurality of channel sacrificial layers 110S and channel layers 110C are alternatingly stacked on the substrate 101 (FIG. 3A).

In step S20, the device structure 20′ may be patterned to form 1^{st} to 3^{rd} recesses R1-R3 having a depth DT1 in the substrate 101 and 1^{st} to 3^{rd} channel structures C1-C3 such that the 1^{st} recess R1 is formed between the 1^{st} channel structure C1 and the 3^{rd} channel structure C3, the 2^{nd} recess R2 is formed between the 1^{st} channel structure C1 and the 2^{nd} channel structure C2, and the 3^{rd} recess R3 is formed at a side of the 2^{nd} channel structure C2 opposite to the 1^{st} recess R1 with respect to the 2^{nd} recess R2 (FIG. 3B).

In step S30, an isolation structure 121 may be formed on the device structure 20′ to fill the 1^{st} recess R1 and the 2^{nd} recess R2 with a 1^{st} portion 121A and a 2^{nd} portion 121B of the isolation structure 121 having a thickness TH1 in the substrate 101 equal to the depth DT1 (FIG. 3C).

In step S40, the device structure 20′ may be patterned again to form a 4^{th} recess R4 and a 5^{th} recess R5 at both sides of the 1^{st} portion 121A of the isolation structure 121 to have a depth DT2 in the substrate 101 which is smaller than the depth DT1 and the thickness TH1 (FIG. 3D).

In step S50, a 1^{st} active isolation structure 203A may be formed in the 4^{th} recess R4 and the 5^{th} recess R5, and a 2^{nd} active isolation structure 103B may be formed in the 3^{rd} recess R3, below a level of a top surface of the substrate 101, such that the 1^{st} active isolation structure 203A has a thickness TH2 equal to the depth DT2 and the 2^{nd} active isolation structure 103B has a thickness TH1 equal to the depth DT1 (FIGS. 3E-3G).

In step S60, a dummy gate structure 150D may be formed to surround the 1^{st} to 3^{rd} channel structures C1-C3, and 1^{st} to 3^{rd} source/drain patterns 115, 125 and 135 may be formed from the 1^{st} to 3^{rd} channel structures C1-C3, respectively, based on the dummy gate structure 150D (FIG. 3H).

In step S70, the dummy gate structure 150D and channel sacrificial layers 110S included in the 1^{st} to 3^{rd} channel structures C1-C3 may be removed, and a 1^{st} work-function metal layer W1 and a 2^{nd} work-function metal layer W2 may be formed to respectively surround 1^{st} to 3^{rd} channel layers 110, 120 and 130 of the 1^{st} to 3^{rd} channel structures C1-C3, and the 1^{st} portion 121A and the 2^{nd} portion 121B of the isolation structure 121, respectively (FIGS. 3I-3J).

In step S80, a gate electrode 150E may be formed to surround the 1^{st} work-function metal layer W1 and the 2^{nd} work-function metal layer W2 (FIG. 3K).

In step S90, a device structure obtained in the previous step may be patterned or planarized at its top surface to form the 1^{st} portion 121A and the 2^{nd} portion 121B of the isolation structure 121 as a gate cut structure 209 and an isolation wall 108 of a semiconductor device including the gate cut structure 209 and a forksheet transistor structure with the isolation wall 108 (FIG. 3L).

The gate cut structure 209 formed by the patterning or planarization operation in this step, may separate the gate electrode 150E into 1^{st} to 3^{rd} gate electrodes E1-E3 for 1^{st} to 3^{rd} transistors 100-300, respectively, and separate the 1^{st} work-function metal layer W1 into a 1^{st} work-function metal layer W1 for the 1^{st} transistor 100 and a 3^{rd} work-function metal layer W3 for the 3^{rd} transistor 300. Further, the isolation wall 108 may separate the 1^{st} channel layers 110, the 1^{st} source/drain regions 115, and the 1^{st} gate electrode E1 and the 1^{st} work-function metal layer W1 from the 2^{nd} channel layers 120, the 2^{nd} source/drain regions 125, and the 2^{nd} gate electrode E2 and the 2^{nd} work-function metal layer W2, respectively.

In the above embodiments, the 1^{st} work-function metal layer W1 of the 1^{st} transistor 100 and the 3^{rd} work-function metal layer W3 of the 3^{rd} transistor 300 may be formed to include the same material for the same polarity or the same gate threshold voltage, different from the 2^{nd} work-function metal layer W2 of the 2^{nd} transistor 200. However, the disclosure is not limited thereto. According to one or more other embodiments, all of the work-function metal layers W1-W3 may be formed of the same material or different materials for the same or different polarities or gate threshold voltages, or any two of the work-function metal layers W1-W3 may be formed of the same material for the same polarity or gate threshold voltage.

In the above embodiments, early formation of a gate cut structure is performed between a forksheet transistor structure (nanosheet transistors 100 and 200) and another transistor structure (nanosheet transistor 300). However, the early formation of a gate cut structure may apply between other types of transistor structures such as FinFETs, nanosheet transistors, vertical field-effect transistors (VFETs), and a combination thereof, not being limited thereto.

In the above embodiments, early formation of a gate cut structure is performed between a forksheet transistor structure (nanosheet transistors 100 and 200) and another transistor structure (nanosheet transistor 300) formed in a single stack or level. However, the early formation of a gate cut structure may apply to a multi-stack or three-dimensional stacked semiconductor device in which transistors are formed at two or more stacks or levels.

In the above embodiments, early formation of a gate cut structure is applied to a semiconductor device including transistor structures formed on a substrate. However, the early formation of a gate cut structure may apply to a semiconductor device including transistor structures having a backside power distribution network (BSPDN) in which the substrate is replaced by a backside isolation structure.

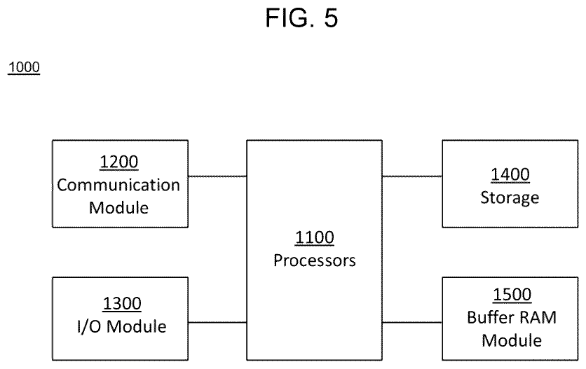

FIG. 5 is a schematic block diagram illustrating an electronic device including a semiconductor device including a forksheet transistor structure and a gate cut structure, according to one or more embodiments. This semiconductor device may be one of the semiconductor devices shown in FIG. 2.

Referring to FIG. 8, an electronic device 1000 may include at least one processor 1100, a communication module 1200, an input/output module 1300, a storage 1400, and a buffer random access memory (RAM) module 1500. The electronic device 1000 may be a mobile device such as a smartphone or a tablet computer, not being limited thereto, according to embodiments.

The processor 1100 may include a central processing unit (CPU), a graphic processing unit (GPU) and/or any other processors that control operations of the electronic device 1000. The communication module 1200 may be implemented to perform wireless or wire communications with an external device. The input/output module 1300 may include at least one of a touch sensor, a touch panel a key board, a mouse, a proximate sensor, a microphone, etc. to receive an input, and at least one of a display, a speaker, etc. to generate an output signal processed by the processor 1100. The storage 1400 may be implemented to store user data input through the input/output module 1300, the output signal, etc. The storage 1400 may be an embedded multimedia card (eMMC), a solid state drive (SSD), a universal flash storage (UFS) device, etc.

The buffer RAM module 1500 may temporarily store data used for processing operations of the electronic device 1000. For example, the buffer RAM 1500 may include a volatile memory such as double data rate (DDR) synchronous dynamic random access memory (SDRAM), low power double data rate (LPDDR) SDRAM, graphics double data rate (GDDR) SDRAM, Rambus dynamic random access memory (RDRAM), etc.

The electronic device 1000 may further include at least one sensor such as an image sensor.

At least one component in the electronic device 1000 may be formed based on a semiconductor device including a forksheet transistor structure and a gate cut structure, according to one or more embodiments.

The foregoing is illustrative of example embodiments and is not to be construed as limiting the disclosure. Although a few example embodiments have been described, those skilled in the art will readily appreciate that many modifications are possible in the above embodiments without materially departing from the disclosure.

1. A semiconductor device comprising:
a 1^{st} transistor comprising a 1^{st} channel structure and a 1^{st} gate structure on the 1^{st} channel structure;
a 2^{nd} transistor comprising a 2^{nd} channel structure and a 2^{nd} gate structure on the 2^{nd} channel structure;
a 3^{rd} transistor comprising a 3^{rd} channel structure and a 3^{rd} gate structure on the 3^{rd} channel structure;
an isolation wall between the 1^{st} channel structure and the 2^{nd} channel structure;
a gate cut structure between the 1^{st} gate structure and the 3^{rd} gate structure; and
a 1^{st} active isolation structure between the 1^{st} channel structure and the 3^{rd} channel structure, below a level of a bottom surface of the 1^{st} channel structure or the 3^{rd} channel structure,
wherein the gate cut structure penetrates the 1^{st} active isolation structure through a bottom surface of the 1^{st} active isolation structure.

2. The semiconductor device of claim 1, wherein the 1^{st} transistor and the 2^{nd} transistor further comprise a 1^{st} source/drain pattern and a 2^{nd} source/drain pattern, respectively, and
wherein the isolation wall extends to be between the 1^{st} source/drain pattern and the 2^{nd} source/drain pattern, and between the 1^{st} gate structure and the 2^{nd} gate structure.

3. The semiconductor device of claim 1, wherein each of the 1^{st} channel structure and the 2^{nd} channel structure comprises a plurality of channel layers arranged one above another.

4. The semiconductor device of claim 1, wherein the 1^{st} transistor, the 2^{nd} transistor, and the 3^{rd} transistor further comprise a 1^{st} source/drain pattern, a 2^{nd} source/drain pattern, and a 3^{rd} source/drain pattern, respectively, and
wherein the isolation wall contacts the 1^{st} channel structure and the 2^{nd} channel structure, the 1^{st} source/drain pattern and the 2^{nd} source/drain pattern, and the 1^{st} gate structure and the 2^{nd} gate structure.

5. The semiconductor device of claim 4, wherein the gate cut structure contacts the 1^{st} gate structure and the 3^{rd} gate structure, and
wherein the gate cut structure is spaced apart from the 1^{st} channel structure, the 1^{st} source/drain pattern, the 3^{rd} channel structure, and the 3^{rd} source/drain pattern.

6. The semiconductor device of claim 1, wherein bottom surfaces of the isolation wall and the gate cut structure are at a same level below a level of a bottom surface of the 1^{st} active isolation structure.

7. The semiconductor device of claim 1, wherein the 1^{st} gate structure comprises a 1^{st} work-function metal layer on the 1^{st} channel structure and a 1^{st} gate electrode on the 1^{st} work-function metal layer,
wherein the 2^{nd} gate structure comprises a 2^{nd} work-function metal layer on the 2^{nd} channel structure and a 2^{nd} gate electrode on the 2^{nd} work-function metal layer,
wherein the 3^{rd} gate structure comprises a 3^{rd} work-function metal layer on the 3^{rd} channel structure and a 3^{rd} gate electrode on the 3^{rd} work-function metal layer, and
wherein the 1^{st} work-function metal layer is on a 1^{st} side surface of the gate cut structure, and the 3^{rd} work-function metal layer is on a 2^{nd} side surface, opposite to the 1^{st} side surface, of the gate cut structure.

8. The semiconductor device of claim 7, wherein the 1^{st} work-function metal layer and the 3^{rd} work-function metal layer are on a top surface of the 1^{st} active isolation structure.

9. The semiconductor device of claim 1, further comprising a 2^{nd} active isolation structure at a side of the 2^{nd} channel structure, opposite to the 3^{rd} channel structure, below a level of a bottom surface of the 2^{nd} channel structure,
wherein a bottom surface of the 2^{nd} active isolation structure is at a level below the bottom surface of the 1^{st} active isolation structure.

10. The semiconductor device of claim 9, wherein the 1^{st} active isolation structure is formed in a substrate between an upper portion of the substrate below the 1^{st} channel structure and an upper portion of the substrate below the 3^{rd} channel structure, and
wherein the 2^{nd} active isolation structure is formed in the substrate at a side of the upper portion of the substrate below the 1^{st} channel structure.

11. The semiconductor device of claim 1, wherein the 1^{st} channel structure and the 3^{rd} channel structure are spaced apart from the gate cut structure by a same distance.

12. The semiconductor device of claim 1, wherein the 1^{st} active isolation structure is formed in a substrate between an upper portion of the substrate below the 1^{st} channel structure and an upper portion of the substrate below the 3^{rd} channel structure.

13. A semiconductor device comprising:
a 1^{st} transistor structure comprising a 1^{st} channel structure;
a 2^{nd} transistor structure comprising a 2^{nd} channel structure, and disposed at a 1^{st} side of the 1^{st} transistor structure;
a 1^{st} active isolation structure between the 1^{st} channel structure and the 2^{nd} channel structure, below a bottom surface of the 1^{st} channel structure or the 2^{nd} channel structure; and
a 2^{nd} active isolation structure at a 2^{nd} side of the 1^{st} transistor structure, opposite to the 1^{st} side, below the bottom surface of the 1^{st} channel structure or the 2^{nd} channel structure,
wherein a bottom surface of the 1^{st} active isolation structure is at a level above a bottom surface of the 2^{nd} active isolation structure.

14. The semiconductor device of claim 13, wherein the 1^{st} transistor structure comprises a 1^{st} transistor and a 2^{nd} transistor between which an isolation wall is formed,
wherein the 1^{st} transistor comprise at least one 1^{st} channel layer, and the 2^{nd} transistor comprises at least one 2^{nd} channel layer,
wherein the 1^{st} active isolation structure is between the 1^{st} channel structure and the 2^{nd} channel structure below a level of a bottom surface of the 1^{st} channel structure or the 2^{nd} channel structure, and
wherein the 2^{nd} active isolation structure is at a side of the 1^{st} channel structure, opposite to the 1^{st} active isolation structure, below a level of the bottom surface of the 1^{st} channel structure.

15. The semiconductor device of claim 14, wherein each of the at least one 1^{st} channel layer and the at least one 2^{nd} channel layer comprises a plurality of channel layers arranged one above another.

16. The semiconductor device of claim 13, further comprising a gate cut structure between a 1^{st} gate structure of the 1^{st} transistor structure and a 2^{nd} gate structure of the 2^{nd} transistor structure.

17. The semiconductor device of claim 16, wherein the gate cut structure penetrates the 1^{st} active isolation structure through a bottom surface of the 1^{st} active isolation structure.

18. A semiconductor device comprising:
a 1^{st} transistor structure comprising a 1^{st} channel structure and a 1^{st} gate structure on the 1^{st} channel structure;
a 2^{nd} transistor structure comprising a 2^{nd} channel structure and a 2^{nd} gate structure on the 2^{nd} channel structure, and disposed at a side of the 1^{st} transistor structure;
a 1^{st} isolation structure between the 1^{st} fin structure and the 2^{nd} gate structure; and
a 1^{st} active isolation structure between the 1^{st} channel structure and the 2^{nd} channel structure, below a bottom surface of the 1^{st} channel structure or the 2^{nd} channel structure,
wherein the 1^{st} isolation structure penetrates the 1^{st} active isolation structure through a bottom surface of the 1^{st} active isolation structure.

19. The semiconductor device of claim 18, wherein the 1^{st} transistor structure comprises a 1^{st} work-function metal layer and a 1^{st} gate electrode on the 1^{st} work-function metal layer,
wherein the 2^{nd} transistor structure comprises a 2^{nd} work-function metal layer and a 2^{nd} gate electrode on the 2^{nd} work-function metal layer, and
wherein the 1^{st} isolation structure is between the 1^{st} gate electrode and the 2^{nd} gate electrode.

20. The semiconductor device of claim 19, wherein the 1^{st} transistor structure comprises:
a 1^{st} transistor comprising at least one 1^{st} channel layer, a 1^{st} source/drain pattern on the at least one 1^{st} channel layer;
a 2^{nd} transistor comprising at least one 2^{nd} channel layer, a 2^{nd} source/drain pattern on the at least one 2^{nd} channel layer; and
a 2^{nd} isolation structure between the at least one 1^{st} channel layer and at least one 2^{nd} channel layer and between the 1^{st} source/drain pattern and the 2^{nd} source/drain pattern.

21-27. (canceled)
